(19) United States
(12) Patent Application Publication
(10) Pub. No.: US 2022/0246632 A1
(43) Pub. Date: Aug. 4, 2022

(54) SEMICONDUCTOR DEVICE AND SEMICONDUCTOR STORAGE DEVICE

(71) Applicant: KIOXIA CORPORATION, Tokyo (JP)

(72) Inventor: Takeshi SHIMANE, Matsudo Chiba (JP)

(21) Appl. No.: 17/409,993

(22) Filed: Aug. 24, 2021

(30) Foreign Application Priority Data
Feb. 2, 2021 (JP) 2021-015171

(51) Int. Cl. H01L 27/11573; H01L 25/065; H01L 27/11556; H01L 27/11529; H01L 27/11582; H01L 29/10

(52) U.S. Cl. CPC H01L 27/11573; H01L 25/0657; H01L 27/11556; H01L 27/11529; H01L 2225/06586; H01L 29/1083; H01L 29/1087; H01L 2225/06506; H01L 2225/06562; H01L 27/11582

(57) ABSTRACT

A semiconductor device includes a semiconductor substrate that includes a first surface and a second surface, a semiconductor region between the first and second surfaces, a first well region in the first surface and having one of a donor concentration and a acceptor concentration higher than the semiconductor region, a second well region between the first well region and the second surface and having a higher acceptor concentration than the semiconductor region, a third well region between the second well region and the second surface and having a higher donor concentration than the semiconductor region, a conductor surrounding at least a portion of the first well region along the first surface and extending from the first surface to the third well region in a first direction intersecting the first surface, and an insulator between the conductor and the first well region and between the conductor and the second well region.

### CROSS-REFERENCE TO RELATED APPLICATION

This application is based upon and claims the benefit of priority from Japanese Patent Application No. 2021-015171, filed Feb. 2, 2021, the entire contents of which are incorporated herein by reference.

### FIELD

Embodiments described herein relate generally to a semiconductor device and a semiconductor storage device.

### BACKGROUND

A semiconductor device such as a semiconductor storage device including a memory cell array and a peripheral circuit is known.

### BRIEF DESCRIPTION OF THE DRAWINGS

FIG. 1 is a schematic cross-sectional view of a semiconductor storage device.

FIG. 2 is a block diagram of a memory chip.

FIG. 3 is a circuit diagram of a memory cell array.

FIG. 4 is a schematic cross-sectional view of a memory chip in a first example.

FIG. 5 is a schematic cross-sectional view of a field effect transistor.

FIG. 6 is a schematic plan view illustrating a planar structure of a semiconductor substrate.

FIG. 7 is a schematic cross-sectional view of a memory pillar.

FIG. 8 through FIG. 12 depict a manufacturing method of a semiconductor storage device.

FIG. 13 is a schematic cross-sectional view of a memory chip in a second example.

FIG. 14 is a schematic cross-sectional view of a memory chip in a third example.

FIG. 15 depicts a threshold voltage distribution of a multi-valued memory.

FIG. 16 depicts a shifted threshold voltage distribution of a multi-valued memory.

### DETAILED DESCRIPTION

Embodiments provide a semiconductor device with high reliability.

In general, according to one embodiment, a semiconductor device includes a semiconductor substrate that includes a first surface and a second surface, a semiconductor region between the first and second surfaces, a first well region in the first surface and having one of a donor concentration and a acceptor concentration higher than the semiconductor region, a second well region between the first well region and the second surface and having a higher acceptor concentration than the semiconductor region, a third well region between the second well region and the second surface and having a higher donor concentration than the semiconductor region, a conductor surrounding at least a portion of the first well region along the first surface and extending from the first surface to the third well region in a first direction intersecting the first surface, and an insulator between the conductor and the first well region and between the conductor and the second well region.

Hereinafter, embodiments will be described with reference to the drawings. The relationship between the thickness of each component and the plane dimension illustrated in the drawings, the ratio of the thickness of each component, and the like may differ from those of an actual product. Further, in the embodiments, substantially the same components are designated by the same reference numerals, and the description thereof is not repeated.

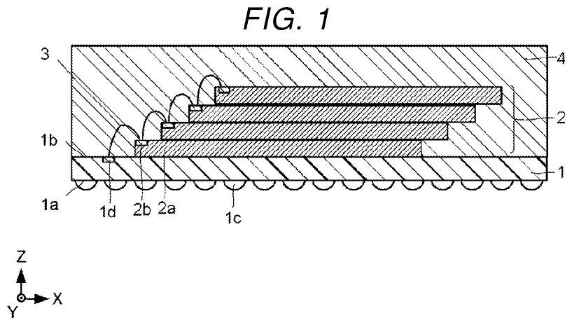

FIG. 1 is a schematic cross-sectional view of a semiconductor storage device, and illustrates an X axis direction along a surface 1a of a wiring substrate 1, a Y axis direction substantially perpendicular to the X axis direction, and a Z axis direction substantially perpendicular to the surface 1a. The semiconductor storage device includes the wiring substrate 1, a chip stacked body 2, a plurality of bonding wires 3, and an insulating resin layer 4.

The wiring substrate 1 includes the surface 1a, a surface 1b opposite to the surface 1a, a plurality of external connection terminals 1c provided on the surface 1a, and a plurality of bonding pads 1d provided on the surface 1b. Examples of the wiring substrate 1 include a printed wiring board (PWB). The surfaces 1a and 1b extend, for example, along the X axis direction and the Y axis direction. The thickness direction of the wiring substrate 1 is, for example, the Z axis direction.

The external connection terminal 1c is formed of, for example, gold, copper, solder or the like. The external connection terminal 1c may be formed of, for example, lead-free solder such as tin-silver-based or tin-silver-copper-based solder. In addition, the external connection terminal 1c may be formed by a stacked layer of a plurality of metal materials. In FIG. 1, the external connection terminals 1c are formed by conductive balls, but the external connection terminals 1c may be formed by bumps.

The plurality of bonding pads 1d are connected to the plurality of external connection terminals 1c via internal wirings of the wiring substrate 1. The plurality of bonding pads 1d includes, for example, a metal element such as copper, silver, gold, or nickel. For example, the plurality of bonding pads 1d may be formed by forming a plating film including such a metal element using an electrolytic plating method, an electroless plating method, or the like. In addition, the plurality of bonding pads 1d may be formed by a conductive paste.

The chip stacked body 2 includes a plurality of memory chips 2a. The plurality of memory chips 2a are stacked, for example, on the surface 1b of the wiring substrate 1 in the Z axis direction such that two adjacent memory chips 2a partially overlap each other. The plurality of memory chips 2a adhere to each other with, for example, an adhesive layer such as a die attach film interposed therebetween. The chip stacked body 2 illustrated in FIG. 1 includes four memory chips 2a, but the number of the memory chips 2a is not limited to four.

The plurality of memory chips 2a each include at least one connection pad 2b. The plurality of memory chips 2a are connected to each other in parallel via the plurality of bonding wires 3 and also are connected to each other to the bonding pads 1d in series.

The insulating resin layer 4 covers the chip stacked body 2. The insulating resin layer 4 includes an inorganic filler such as silicon oxide (SiO₂). For example, the insulating resin layer 4 is formed of a sealing resin obtained by mixing an inorganic filler with an organic resin or the like by a transfer molding method, a compression molding method, an injection molding method, or the like.

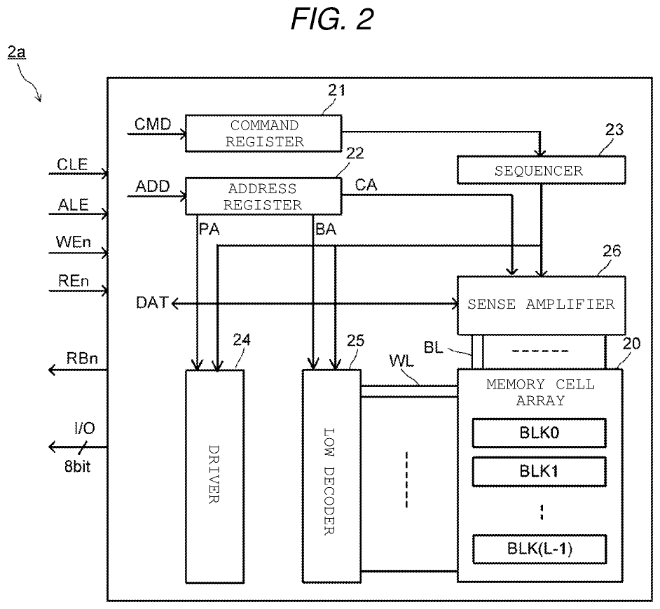

FIG. 2 is a block diagram of the memory chip 2a. The memory chip 2a includes a memory cell array 20, a command register 21, an address register 22, a sequencer 23, a driver 24, a low decoder 25, and a sense amplifier 26.

The memory cell array 20 includes a plurality of blocks BLK (BLK0 to BLK(L−1) (where L is a natural number of 2 or more)). The blocks BLK include a plurality of memory transistors MT that store data in a non-voluntary manner.

The memory cell array 20 is connected to a plurality of word lines WL and a plurality of bit lines BL. Each memory transistor MT is connected to one of the plurality of word lines WL and one of the plurality of bit lines BL.

The command register 21 stores a command signal CMD received from a memory controller. The command signal CMD includes, for example, instruction data that causes the sequencer 23 to perform a read operation, a write operation, and an erasing operation.

The address register 22 stores address data conveyed by an address signal ADD from the memory controller. The address signal ADD includes, for example, a block address BA, a page address PA, and a column address CA. For example, the block address BA, the page address PA, and the column address CA are used for selecting one of the blocks BLK, one of the word lines WL, and one of the bit lines BL, respectively.

The sequencer 23 controls an operation of the memory chip 2a. The sequencer 23 controls the driver 24, the low decoder 25, the sense amplifier 26, and the like, for example, based on the command signal CMD, and performs operations such as the read operation, the write operation, and the erasing operation.

The driver 24 generates a voltage to be used for the read operation, the write operation, the erasing operation, and the like. The driver 24 includes, for example, a DA converter. Also, the driver 24 applies the generated voltage to signal lines corresponding to the selected word lines WL, for example, based on the page address PA stored in the address register 22.

The low decoder 25 selects one block BLK in the corresponding memory cell array 20 based on the block address BA stored in the address register 22. Also, the low decoder 25 applies, for example, the voltage applied to the signal line corresponding to the selected word line WL, to the selected word line WL in the selected block BLK.

In the write operation, the sense amplifier 26 applies a desired voltage to each bit line BL according to write data DAT received from the memory controller. In addition, in the read operation, the sense amplifier 26 determines data stored in the memory cell based on the voltage applied to the bit line BL and transmits a determination result to the memory controller as read data DAT.

The communication between the memory chip 2a and the memory controller conforms to, for example, a NAND interface standard. For example, the communication between the memory chip 2a and the memory controller includes a command latch enable signal CLE, an address latch enable signal ALE, a write enable signal WEn, a read enable signal REn, a ready busy signal RBn, an input/output signal I/O, and the like.

The command latch enable signal CLE indicates that an input/output signal I/O received by the memory chip 2a is a command signal CMD. The address latch enable signal ALE indicates that a received signal I/O is an address signal ADD. The write enable signal WEn is a signal that instructs the memory chip 2a to input an input/output signal I/O. The read enable signal REn is a signal that instructs an output of an input/output signal I/O to the memory chip 2a.

The ready busy signal RBn is a signal that notifies the memory controller of whether the memory chip 2a is in a ready state (ready to receive an instruction/command from the memory controller) or a busy state (not ready to receive an instruction/command from the memory controller).

The input/output signal I/O is, for example, a signal of an 8-bit width and can include a signal such as a command signal CMD, an address signal ADD, and a write data signal DAT.

The memory chip 2a and the memory controller described above may make up one semiconductor storage device. Examples of the semiconductor storage device include a memory card such as an SD card or a solid-state drive (SSD).

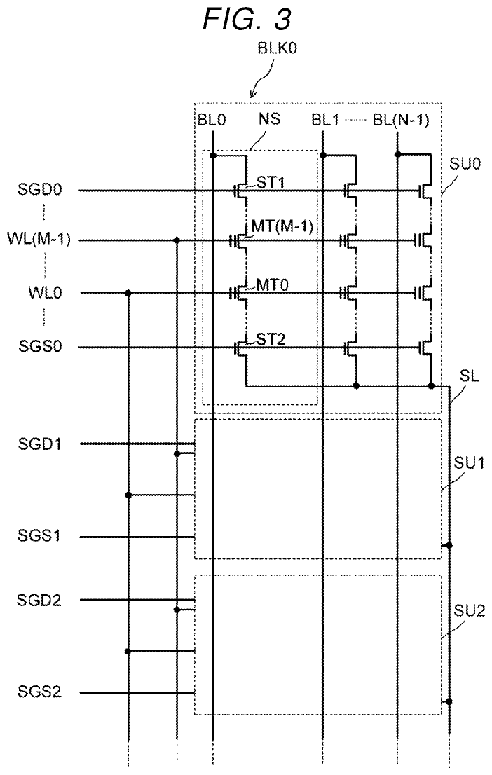

Hereinafter, a circuit configuration of the memory cell array 20 is described. FIG. 3 is a circuit diagram of the memory cell array 20. FIG. 3 illustrates only one block BLK0, but the other blocks BLK have similar configurations.

The block BLK includes a plurality of string units SU. Each of string unit SU includes a plurality of NAND strings NS. In addition, FIG. 3 illustrates three string units SU (SU0 to SU2), but the number of the string units SU is not particularly limited.

Each NAND string NS is connected to one of the plurality of bit lines BL (BL0 to BL(N−1) (where N is a natural number of 2 or more)). Each NAND string NS includes a plurality of memory transistors MT, a select transistor ST1, and a select transistor ST2.

Each memory transistor MT includes a control gate and a charge storage layer, and stores data in a non-voluntary manner. FIG. 3 illustrates a plurality of memory transistors MT (MT0 to MT(M−1) (where M is a natural number of 2 or more)), but the number of the memory transistors MT is not particularly limited. In addition, each NAND string NS may include a dummy memory transistor that has the same structure as the memory transistor MT but does not store data.

The memory transistors MT may be a MONOS type including an insulating film in the charge storage layer and may be an FG type including a conductor layer in the charge storage layer. In the present embodiment, the MONOS type memory transistors MT are used as an example.

Each select transistor ST1 is used for selecting a string unit SU during various operations. The number of the select transistors ST1 is not particularly limited.

Each select transistor ST2 is also used for selecting a string unit SU during various operations. The number of the select transistors ST2 is not particularly limited.

In each NAND string NS, the drain of the select transistor ST1 is connected to a corresponding bit line BL. The source of the select transistor ST1 is connected to one end of the memory transistors MT connected to each other in series. The other end of the memory transistors MT is connected to the drain of the select transistor ST2.

In the same block BLK, the source of the select transistor ST2 is connected to a source line SL. In each string unit SU, the gates of the select transistors ST1 are connected to a corresponding selection gate line SGD. The control gates of the memory transistors MT are connected to corresponding word lines WL. The gates of the select transistors ST2 are connected to a corresponding selection gate line SGS.

The plurality of NAND strings NS to which the same column addresses CA are allocated are connected to the same bit lines BL among the plurality of blocks BLK. The source line SL connects the plurality of blocks BLK to each other.

### First Example of Memory Chip 2a

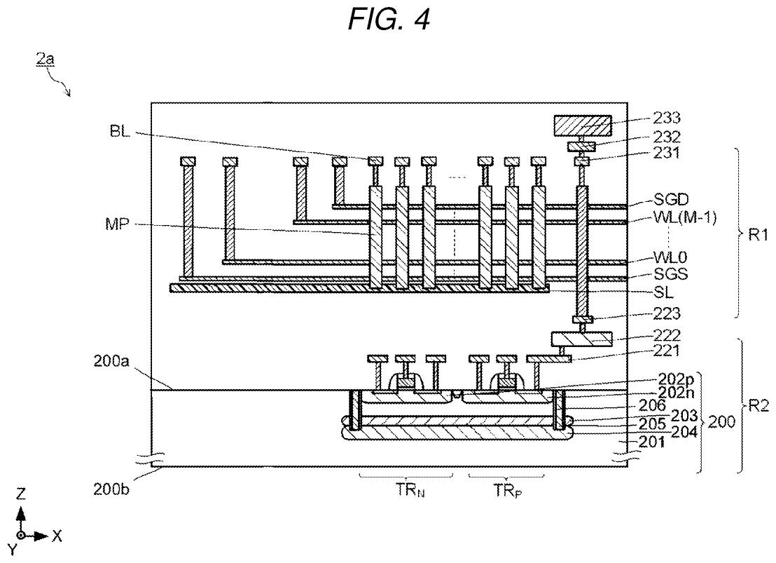

FIG. 4 is a schematic cross-sectional view (X-Z cross section) of the memory chip 2a in a first example.

The memory chip 2a illustrated in FIG. 4 includes a first region R1 including the memory cell array 20 illustrated in FIG. 2 and a second region R2 including peripheral circuits such as the command register 21, the address register 22, the sequencer 23, the driver 24, the low decoder 25, and the sense amplifier 26 illustrated in FIG. 2 under the memory cell array 20 in the Z axis direction.

FIG. 4 illustrates field effect transistors such as a field effect transistor (FET) TR_{N} and a field effect transistor TR_{P} which are provided on a semiconductor substrate 200, conductive layers 221, a conductive layer 222, a conductive layer 223, the source line SL, memory pillars MP, the selection gate line SGS, the word lines WL (the word lines WL0 to the word lines WL(M−1)), the selection gate line SGD, the bit lines BL, conductive layers 231, a conductive layer 232, and a conductive layer 233. Insulating layers are provided between those components, if necessary.

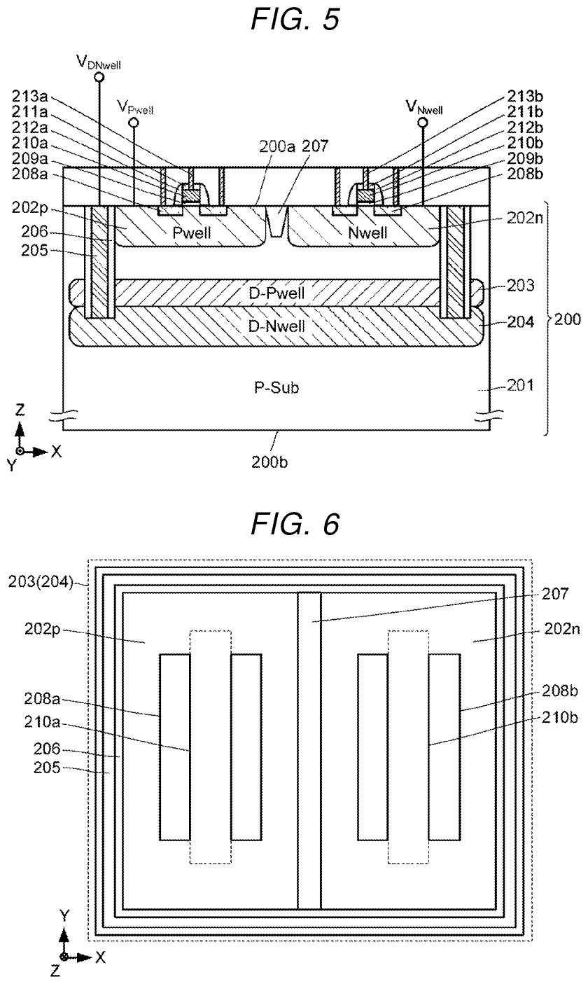

FIG. 5 is a schematic cross-sectional view (X-Z cross section) of the field effect transistor TR_{N} and the field effect transistor TR_{P}.

The semiconductor substrate 200 on which the field effect transistor TR_{N} and the field effect transistor TR_{P} are formed includes a surface 200a and a surface 200b. FIG. 5 further illustrates a semiconductor region 201, a p-type well region (Pwell) 202p, an n-type well region (Novell) 202n, a p-type deep well region (D-Pwell) 203, an n-type deep well region (D-Nwell) 204, a conductor 205, insulators 206, and an element separator 207 provided on the semiconductor substrate 200.

The semiconductor region 201 is a substrate region in the semiconductor substrate 200 and is provided between the surfaces 200a and 200b. The surfaces 200a and 200b extend, for example, along the X axis direction and the Y axis direction. The thickness direction of the semiconductor substrate 200 is, for example, the Z axis direction.

The semiconductor region 201 is provided, for example, between the n-type deep well (D-Nwell) region 204 and the surface 200b. The semiconductor region 201 may be provided between the p-type well (Pwell) region 202p and the p-type deep well (D-Pwell) region 203 and between the n-type well (Novell) region 202n and the p-type deep well region 203. The semiconductor region 201 includes, for example, silicon (Si). The semiconductor region 201 may include, for example, acceptor impurities of boron (B) or the like. The acceptor concentration of the semiconductor region 201 is, for example, 1×10¹³ cm⁻³ to 1×10¹⁶ cm⁻³.

The p-type well region 202p is provided on the surface 200a. The p-type well region 202p includes, for example, acceptor impurities of boron or the like. The p-type well region 202p has a higher acceptor concentration than the semiconductor region 201. For example, the acceptor concentration of the p-type well region 202p is preferably 1×10¹⁷ cm⁻³ to 1×10¹⁹ cm⁻³ so that conditions including the insulation breakdown voltage, the leak current, the endurance, and the like required for the field effect transistor TR_{N} can be satisfied.

The p-type well region 202p is connected to, for example, a power supply circuit that applies a voltage V_{Pwell} to the p-type well region 202p. The voltage V_{Pwell} is, for example, a negative voltage. For example, the power supply circuit may be included in the peripheral circuits.

The n-type well region 202n is provided on the surface 200a. The n-type well region 202n includes, for example, donor impurities such as phosphorus (P) and arsenic (As). The n-type well region 202n has a higher donor concentration than the semiconductor region 201. For example, the donor concentration of the n-type well region 202n is preferably 1×10¹⁷ cm⁻³ to 1×10¹⁹ cm⁻³ so that the conditions including the insulation breakdown voltage, the leak current, and the endurance and the like required for the field effect transistor TR_{P} can be satisfied.

For example, the n-type well region 202n is connected to the power supply circuit that applies a voltage V_{Nwell} to the n-type well region 202n. For example, the voltage V_{Nwell} is a positive voltage. For example, the power supply circuit may be included in the peripheral circuits.

The p-type deep well region 203 is a p-type well region provided at a position deeper than the p-type well region 202p and the n-type well region 202n with respect to the surface 200a. The p-type deep well region 203 is provided between the p-type well region 202p and the surface 200b and between the n-type well region 202n and the surface 200b and is separated from the surface 200a.

The p-type deep well region 203 includes acceptor impurities of boron or the like. The p-type deep well region 203 has a higher acceptor concentration than the semiconductor region 201. For example, the acceptor concentration of the p-type deep well region 203 is preferably 1×10¹⁶ cm⁻³ to 1×10¹⁸ cm⁻³.

The n-type deep well region 204 is an n-type well region provided at a position deeper than the p-type well region 202p and the n-type well region 202n with respect to the surface 200a. The n-type deep well region 204 is provided between the p-type deep well region 203 and the surface 200b and is separated from the surface 200a. The n-type deep well region 204 illustrated in FIG. 5 is in contact with the p-type deep well region 203, but the present disclosure is not limited thereto. In addition, the thickness of the n-type deep well region 204 illustrated in FIG. 5 is greater than the thickness of the p-type deep well region 203, but the present disclosure is not limited thereto.

The n-type deep well region 204 includes donor impurities such as phosphorus and arsenic. The n-type deep well region 204 has a higher donor concentration than the semiconductor region 201. For example, the donor concentration of the n-type deep well region 204 is preferably 1×10¹⁶ cm⁻³ to 1×10¹⁸ cm⁻³.

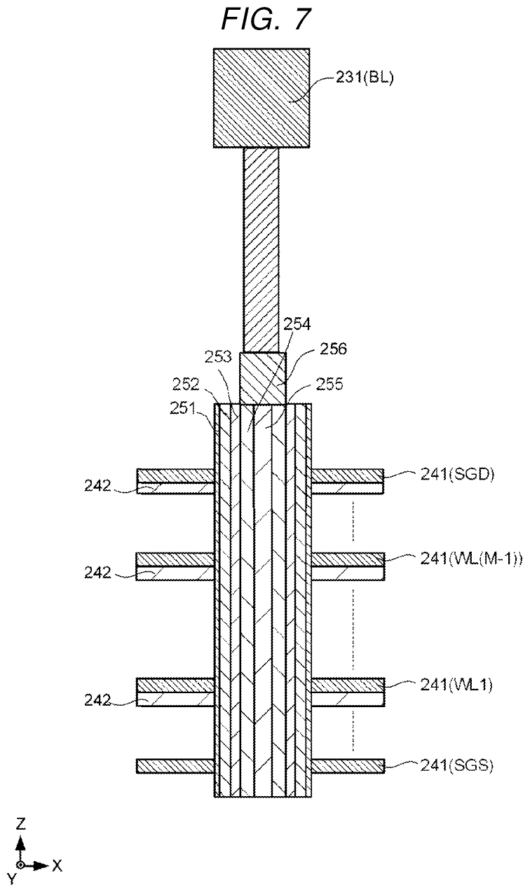

The conductor 205 surrounds at least portions of the p-type well region 202p and the n-type well region 202n along the surface 200a. FIG. 6 is a schematic plan view (X-Y plane) of the semiconductor substrate 200. The conductor 205 illustrated in FIG. 6 surrounds the p-type well region 202p and the n-type well region 202n along the surface 200a. The field effect transistor TR_{N} includes a channel region in the p-type well region 202p. The field effect transistor TR_{P} includes a channel region in the n-type well region 202n.

As illustrated in FIG. 5, the conductor 205 extends from the surface 200a to the n-type deep well region 204 along the direction intersecting to the surface 200a (Z axis direction). That is, the conductor 205 is connected to the n-type deep well region 204. The conductor 205 is electrically connected to the power supply circuit that applies a voltage V_{DNwell} via a contact plug formed on the conductor 205. For example, the voltage V_{DNwell} is a negative voltage.

The conductor 205 preferably includes a material with a higher electrical conductivity than a semiconductor material of the semiconductor region 201 (for example, silicon). Examples of the conductor 205 include a polycrystalline semiconductor doped with donor impurities such as phosphorus and arsenic. Examples of the polycrystalline semiconductor include polysilicon. The present disclosure is not limited thereto, and the conductor 205 may be made of another conductive material such as a metal material.

The insulators 206 are provided between the conductor 205 and the p-type well region 202p, between the conductor 205 and the n-type well region 202n, and between the conductor 205 and the p-type deep well region 203, and the insulator 206 covers the side surface of the conductor 205. The insulator 206 physically separates the conductor 205 from the p-type well region 202p, physically separates the conductor 205 from the n-type well region 202n, and physically separates the conductor 205 from the p-type deep well region 203. The insulator 206 includes, for example, silicon oxide.

The element separator 207 is provided between the field effect transistor TR_{N} and the field effect transistor TR_{P}. The element separator 207 electrically separates the field effect transistor TR_{N} from the field effect transistor TR_{P}. The element separator 207 includes, for example, silicon oxide. The element separator 207 may be referred to as a shallow trench isolation (STI) feature or the like.

The field effect transistor TR_{N} includes a pair of impurity regions 208a, a gate insulating film 209a, a gate electrode 210a, an insulating film 211a, and an insulating layer 212a. The field effect transistor TR_{P} includes a pair of impurity regions 208b, a gate insulating film 209b, a gate electrode 210b, an insulating film 211b, and an insulating layer 212b. In addition, each of the field effect transistors TR_{N} and TR_{P} is an ultra-low breakdown voltage transistor capable of high-speed operations, and can be applied to a peripheral circuit that can perform, for example, low-voltage and high-speed operations. Each of the field effect transistor TR_{N} and the field effect transistor TR_{P} can form any one of the above peripheral circuits in the second region R2 of FIG. 4.

As illustrated in FIG. 5, the pair of impurity regions 208a is provided in the p-type well region 202p. Each impurity region 208a forms the source region or the drain region of the field effect transistor TR_{N}. The field effect transistor TR_{N} includes a channel region between the impurity regions 208a. The impurity regions 208a include, for example, donor impurities. Each of the impurity regions 208a is connected to a contact plug 213a.

As illustrated in FIG. 5, the pair of impurity regions 208b is provided in the n-type well region 202n. As illustrated in FIG. 5, each of the impurity regions 208b forms the source region or the drain region of the field effect transistor TR_{P}. The field effect transistor TR_{P} includes a channel region between the impurity regions 208b. The impurity region 208b includes, for example, acceptor impurities. Each of the impurity regions 208b is connected to a contact plug 213b.

As illustrated in FIG. 5, the gate insulating film 209a is provided above the p-type well region 202p. As illustrated in FIG. 5, the gate insulating film 209b is provided above the n-type well region 202n. Each of the gate insulating film 209a and the gate insulating film 209b is, for example, a silicon oxide film.

As illustrated in FIG. 5, the gate electrode 210a is provided on the gate insulating film 209a. As illustrated in FIG. 5, the gate electrode 210b is provided on the gate insulating film 209b. Each of the gate electrode 210a and the gate electrode 210b includes, for example, one or more conductive layers including a doped polysilicon layer containing carbon, a doped polysilicon layer containing phosphorus, a titanium layer, a metal nitride layer including titanium nitride or tungsten nitride, and/or a tungsten layer. The gate electrode 210a and the gate electrode 210b may be formed by stacking those conductive layers. The gate electrode 210a is connected to the contact plug 213a. The gate electrode 210b is connected to the contact plug 213b.

The gate electrode 210a is, for example, electrically connected to a bit line BL.

As illustrated in FIG. 5, the insulating film 211a is provided on the gate electrode 210a. The insulating film 211b is provided on the gate electrode 210b. The insulating film 211a and the insulating film 211b function as etching stoppers, for example, when the contact plugs 213a and 213b are formed on the gate electrode 210a and the gate electrode 210b, respectively. The insulating film 211a and the insulating film 211b are, for example, silicon nitride (SiN) films.

Each of the insulating layer 212a and the insulating layer 212b may include, for example, a first insulating layer and a second insulating layer provided on the first insulating layer. The first insulating layer and the second insulating layer are provided on a side surface of the stacked layers of the gate electrode 210a and the insulating film 211a and a side surface of the stacked layers of the gate electrode 210b and the insulating film 211b, and extend along the thickness direction of the stacked layers. The first insulating layer is, for example, a silicon dioxide (SiO₂) layer. The second insulating layer is, for example, a silicon nitride (SiN) layer. The insulating layer 212a and the insulating layer 212b function as side walls of the field effect transistor TR_{N} and the field effect transistor TR_{P}, respectively.

As illustrated in FIG. 5, the channel region of each of the field effect transistor TR_{N} and the channel region of the field effect transistor TR_{P} is surrounded by the insulators 206, the p-type deep well region 203, and the n-type deep well region 204. The structure is referred to as a triple well structure. At least one of the field effect transistor TR_{N} and the field effect transistor TR_{P} may be surrounded by the insulators 206, the p-type deep well region 203, and the n-type deep well region 204.

As illustrated in FIG. 4, the conductive layers 221, the conductive layer 222, and the conductive layer 223 are connected to the sources or the drains of the field effect transistors via a plurality of contact plugs.

As illustrated in FIG. 4, the source line SL is provided above the field effect transistors. The selection gate line SGS is provided above the source line SL. The word lines WL are sequentially provided above the selection gate line SGS. The selection gate line SGD is provided above the plurality of word lines WL. The bit lines BL are provided above the selection gate line SGD.

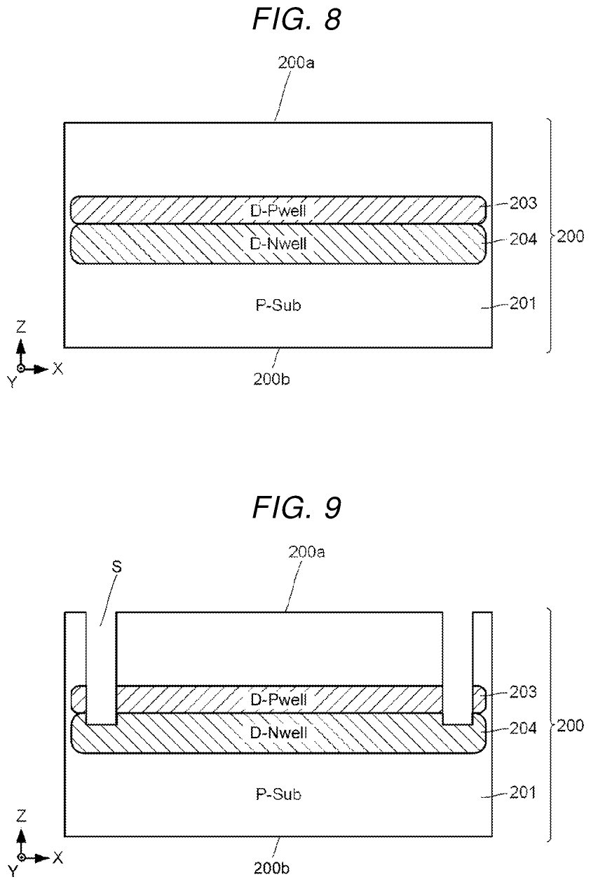

As illustrated in FIG. 4, the memory pillars MP extend along the Z axis direction and penetrate a stacked body including the selection gate line SGS, the plurality of word lines WL, and the selection gate line SGD. Here, the structure of the memory pillar MP is explained. FIG. 7 is a schematic cross-sectional view of the memory pillar MP. FIG. 7 illustrates a conductive layer 241, an insulating layer 242, a block insulating film 251, a charge storage film 252, a tunnel insulating film 253, a semiconductor layer 254, a core insulating layer 255, a cap layer 256, and the conductive layers 231.

As illustrated in FIG. 7, the conductive layers 241 and the insulating layers 242 are alternately stacked to form a stacked body. The plurality of conductive layers 241 include the selection gate line SGS, the word lines WL, and the selection gate line SGD. The conductive layer 241 includes a metal material. For example, the insulating layer 242 includes silicon oxide.

As illustrated in FIG. 7, the block insulating film 251, the charge storage film 252, the tunnel insulating film 253, the semiconductor layer 254, and the core insulating layer 255 make up the memory pillars MP. The components of the memory pillar MP extend along the Z axis direction. One of the memory pillars MP corresponds to one of the NAND strings NS. In addition, the block insulating film 251, the charge storage film 252, and the tunnel insulating film 253 make up a memory layer between the stacked body of the conductive layer 241 and the insulating layer 242 and the semiconductor layer 254.

The block insulating film 251, the tunnel insulating film 253, and the core insulating layer 255 include, for example, silicon oxide. The charge storage film 252 includes, for example, silicon nitride. The semiconductor layer 254 and the cap layer 256 include, for example, polysilicon.

More specifically, a hole that penetrates the plurality of conductive layer 241 and corresponds to the memory pillar MP is formed. The block insulating film 251, the charge storage film 252, and the tunnel insulating film 253 are sequentially stacked on the inner surface of the hole. Also, the semiconductor layer 254 is formed on the tunnel insulating film 253.

The semiconductor layer 254 penetrates the stacked body of the conductive layer 241 and the insulating layer 242 in the Z axis direction. The semiconductor layers 254 include channel regions of the select transistor ST1, the select transistor ST2, and the memory transistors MT. Accordingly, the semiconductor layer 254 functions as a signal line that connects current paths of the select transistor ST1, the select transistor ST2, and the memory transistors MT.

The core insulating layer 255 is provided inside the semiconductor layer 254. The core insulating layer 255 extends along the semiconductor layer 254.

The cap layer 256 is provided on the semiconductor layer 254 and the core insulating layer 255 and also in contact with the tunnel insulating film 253.

One of the conductive layers 231 is in contact with the cap layer 256 via the contact plug. One of the conductive layers 231 corresponds to a bit line BL. The conductive layer 231 includes a metal material.

The memory pillar MP and a conductive layer 241 that functions as a word line WL form a memory transistor MT. The memory pillar MP and the conductive layer 241 that functions as the selection gate line SGD form the select transistor ST1. The memory pillar MP and the conductive layer 241 that functions as the selection gate line SGS form the select transistor ST2.

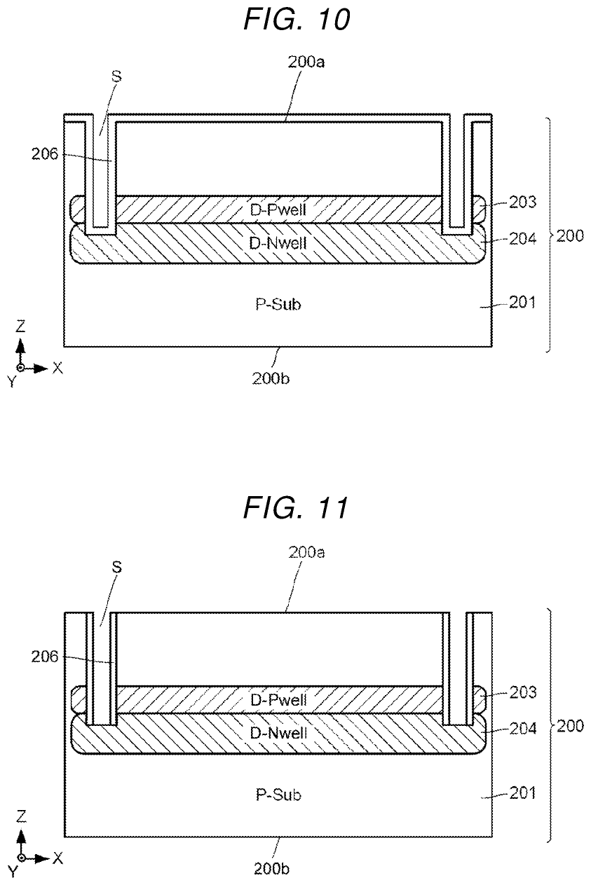

Subsequently, a manufacturing method of the semiconductor storage device is described with reference to FIGS. 8 to 12. FIGS. 8 to 12 are schematic cross-sectional views (X-Z cross sections) of the semiconductor storage device being manufactured. Herein, manufacturing steps for forming the field effect transistor TR_{N} and the field effect transistor TR_{P} are described.

First, as illustrated in FIG. 8, the p-type deep well region 203 and the n-type deep well region 204 are formed in the semiconductor substrate 200. The p-type deep well region 203 is formed by implanting ions of acceptor impurities such as boron from the surface 200a using a mask pattern. The n-type deep well region 204 is formed by implanting ions of donor impurities of phosphorus, arsenic and the like from the surface 200a using a mask pattern. The depth of the p-type deep well region 203 and the depth of the n-type deep well region 204 with respect to the surface 200a can be controlled, for example, by adjusting the acceleration voltage of impurity ions. The impurity concentration can be controlled, for example, by adjusting the dose amount of the impurity ions.

Subsequently, as illustrated in FIG. 9, a part of the semiconductor substrate 200 is removed to form an opening S in the surface 200a. The opening S is a groove for forming the conductor 205 and the insulators 206 therein and is provided in a loop shape along the surface 200a as illustrated in FIG. 6. The opening S extends from the surface 200a to the n-type deep well region 204 in the direction intersecting to the surface 200a (Z axis direction). The part of the semiconductor substrate 200 can be removed, for example, by reactive ion etching (RIE) using a mask pattern.

Subsequently, as illustrated in FIG. 10, the insulator 206 is formed on the surface 200a. The insulator 206 extends to the inner wall surface and the inner bottom surface of the opening S. The insulator 206 is an insulating film such as a silicon oxide film, for example, formed by chemical vapor deposition (CVD). The thickness of the insulator 206 is not particularly limited, as long as the inner surface of the opening S is fully covered with the insulator 206.

Subsequently, as illustrated in FIG. 11, the surface 200a is exposed by partially removing the insulator 206, and the n-type deep well region 204 is partially exposed on the inner bottom surface of the opening S. The insulator 206 can be partially removed, for example, by using reactive ion etching.

Subsequently, as illustrated in FIG. 12, the conductor 205 are formed in the opening S. For example, the conductor 205 is a polycrystalline semiconductor layer formed to fill the opening S. The polycrystalline semiconductor layer includes doped donor impurities of phosphorus, arsenic, and the like. The polycrystalline semiconductor layer may be formed by forming an amorphous semiconductor layer, doping the amorphous semiconductor layer with donor impurities, and crystallizing the amorphous semiconductor layer by a heat treatment. The present disclosure is not limited to this, and the conductor 205 may be a layer including a metal material formed to fill the opening.

Thereafter, the field effect transistor TR_{P} and the field effect transistor TR_{N} can be formed by forming the element separator 207, the impurity regions 208a and 208b, the gate insulating films 209a and 209b, the gate electrodes 210a and 210b, the insulating film 211a and 211b, the insulating layer 212a and 212b, and the contact plugs 213a and 213b as illustrated in FIG. 5. Any known method can be used to form each component.

### Second Example of Memory Chip 2a

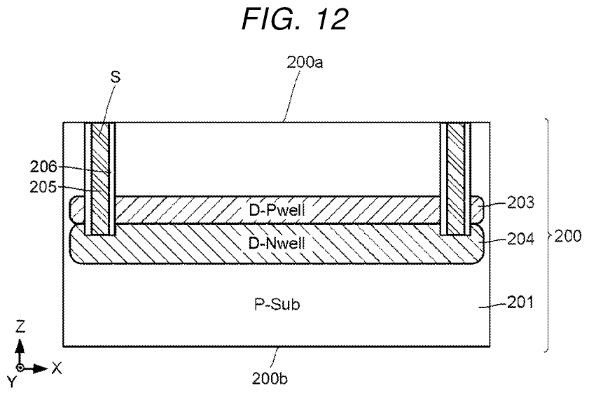

FIG. 13 is a schematic cross-sectional view (X-Z cross section) of the memory chip 2a in a second example. The descriptions for the components same as the first example may be omitted.

The memory chip 2a illustrated in FIG. 13 includes the first region R1 including the memory cell array 20 illustrated in FIG. 2 and the second region R2 that is provided near the memory cell array 20 and includes peripheral circuits such as the command register 21, the address register 22, the sequencer 23, the driver 24, the low decoder 25, and the sense amplifier 26 illustrated in FIG. 2.

FIG. 13 illustrates the field effect transistor TR_{N} and the field effect transistor TR_{P} provided in the semiconductor substrate 200, the conductive layers 221, the memory pillars MP, the selection gate line SGS, the word lines WL (the word lines WL0 to the word lines WL(M−1)), the selection gate line SGD, the bit lines BL, and the conductive layers 231.

The semiconductor substrate 200 further includes a p-type semiconductor region 219p. The p-type semiconductor region 219p is provided under the memory cell array 20 and in the surface 200a. The p-type semiconductor region 219p includes, for example, acceptor impurities such as boron.

The p-type semiconductor region 219p has a higher acceptor concentration than the semiconductor region 201. The p-type semiconductor region 219p is connected to the source line SL via a contact plug. The other structures of the semiconductor substrate 200 are the same as the structures illustrated in FIGS. 5 and 6, and thus repeated description is omitted here.

The field effect transistor TR_{N} and the field effect transistor TR_{P} have the same structures as illustrated in FIGS. 5 and 6, and thus the description is omitted here.

The memory pillar MP penetrates the stacked body including the selection gate line SGS, the plurality of word lines WL, and the selection gate line SGD to be connected to the p-type semiconductor region 219p. The memory pillar MP has the same structure as illustrated in FIG. 7, and thus the description is omitted here.

### Third Example of Memory Chip 2a

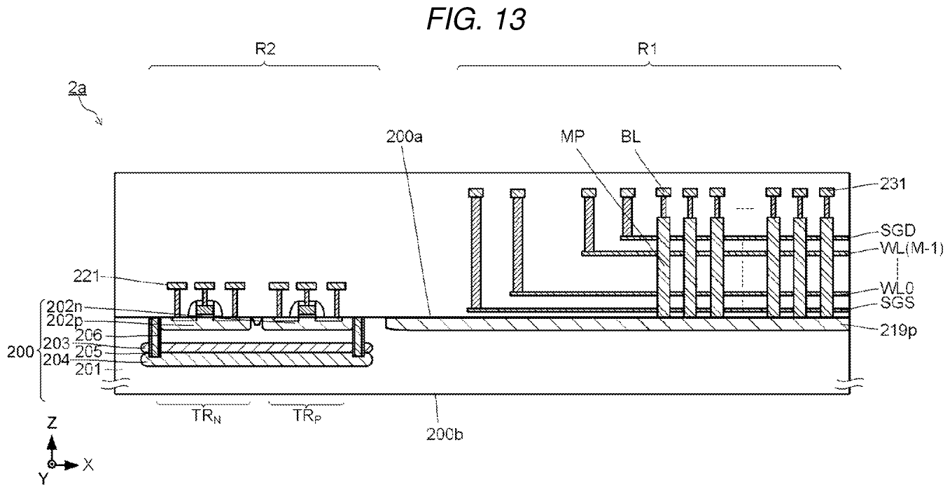

FIG. 14 is a schematic cross-sectional view (X-Z cross section) of the memory chip 2a in a third example. The descriptions for the components same as the first example may be omitted.

The memory chip 2a illustrated in FIG. 14 includes the first region R1 including the memory cell array 20 and the second region R2 that is provided near the memory cell array 20 and includes peripheral circuits such as the command register 21, the address register 22, the sequencer 23, the driver 24, the low decoder 25, and the sense amplifier 26. The first region R1 and the second region R2 are provided on separate substrates that are connected by bonding.

FIG. 14 illustrates the field effect transistor TR_{N} and the field effect transistor TR_{P} provided on the semiconductor substrate 200, the conductive layers 221, conductive layers 224, conductive layers 225, the memory pillars MP provided on a substrate 300, the selection gate line SGS, the word lines WL (the word lines WL0 to the word lines WL(M−1)), the selection gate line SGD, the bit lines BL, the conductive layers 231, conductive layers 234, connection pads 261, and connection pads 262.

The semiconductor substrate 200 has the same structure as illustrated in FIGS. 5 and 6, and thus the description is omitted here.

The field effect transistor TR_{N} and the field effect transistor TR_{P} have the same structures as illustrated in FIGS. 5 and 6, and thus the description is omitted here.

The memory pillars MP penetrate the stacked body including the selection gate line SGS, the plurality of word lines WL, and the selection gate line SGD. The memory pillars MP are connected to the substrate 300, and are also connected to the source line SL via the substrate 300. The other structure of each memory pillar MP is the same as the structure illustrated in FIG. 7, and thus repeated description is omitted here.

One of the conductive layers 225 is connected to the source or the drain of the field effect transistor TR_{N} or the field effect transistor TR_{P} via contact plugs, the conductive layers 221, and the conductive layers 224.

One of the conductive layers 234 is connected to the substrate 300 via contact plugs and the conductive layer 231. Another one of the conductive layers 234 is connected to one of the bit lines BL via a contact plug. Yet another one of the conductive layers 234 is connected to the selection gate line SGS, one of the plurality of word lines WL, or the selection gate line SGD via contact plugs and the conductive layers 231.

The connection pads 261 formed on the semiconductor substrate 200 side are connected to the conductive layers 225 via contact plugs. The connection pad 261 includes, for example, a metal material such as copper or a copper alloy.

The connection pads 262 formed on the substrate 300 side are connected to the conductive layers 234 via contact plugs. The connection pad 262 includes, for example, a metal material such as copper or a copper alloy.

The connection pads 261 and the connection pads 262 are directly joined by, for example, element diffusion between metals, van der Waals force, or recrystallization by volume expansion or melting. Further, the first region R1 and the second region R2 provided on the separate substrates can be bonded by direct joining by element diffusion between insulators, van der Waals force, or chemical reaction such as dehydration condensation or polymerization.

The substrate 300 is, for example, a wiring substrate. However, any other substrate may be used as the substrate 300. The substrate 300 includes, for example, a plurality of electrode pads on its surface. The plurality of electrode pads are connected to the memory pillars MP or the contact plugs.

Subsequently, application examples of the field effect transistor TR_{N} and the field effect transistor TR_{P} in these semiconductor storage devices are described. The field effect transistor TR_{N} and the field effect transistor TR_{P} can be applied, for example, to the sense amplifier 26.

As one of semiconductor storage devices, a multi-valued (multi-bit) memory that can store a plurality of bits of data in each memory cell is known. In order to store a plurality of bits of data in one memory cell, a distribution of a plurality of threshold voltages (Vth) for the memory transistor MT is formed in a voltage range lower than the voltage applied to the gate of the memory transistor MT of a non-selected cell during the read operation.

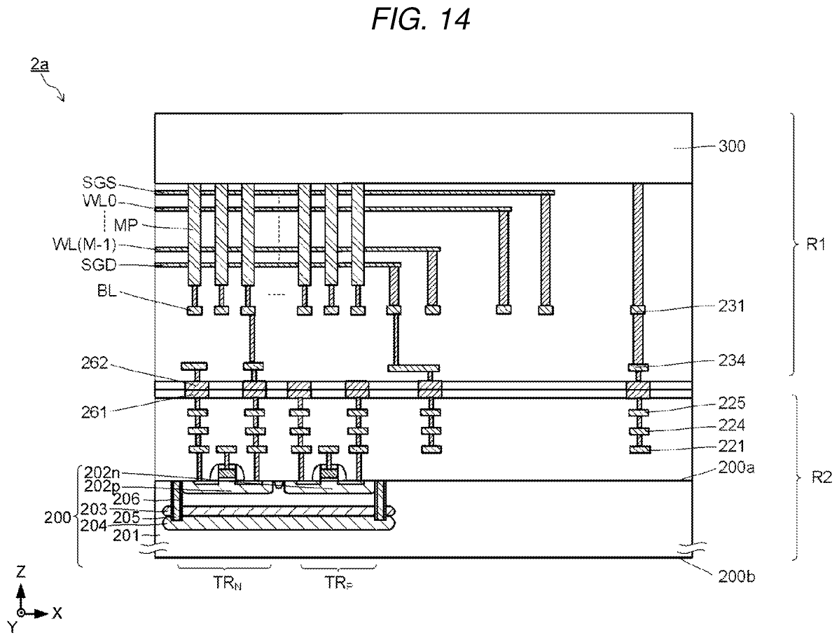

FIG. 15 depicts a threshold voltage distribution in such a multi-valued memory. The horizontal axis represents the threshold voltage level and the vertical axis represents the number of memory cells.

The multi-valued memory requires a high write voltage in order to increase the number of data bits that can be stored. In the multi-valued memory, as the memory cells becomes finer (smaller and/or closer packed), the distribution width at each threshold voltage tends to become wider and problems such as erroneous writing occur more often. Here, by shifting a plurality of threshold voltage distributions to the negative side, even when each threshold voltage distribution is widened, erroneous writing can be avoided and the number of bits of data can be increased by increasing the number of different threshold voltage distributions.

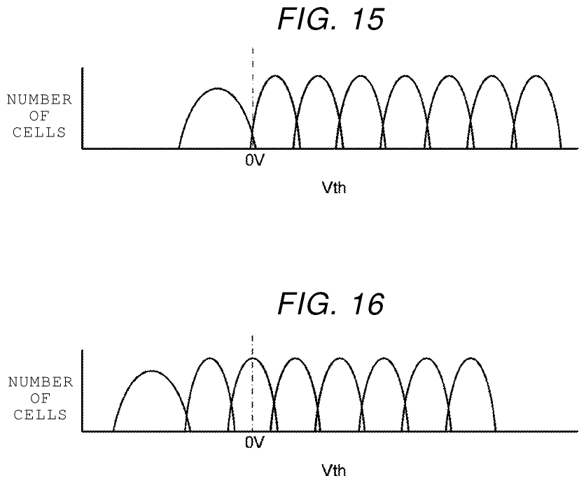

FIG. 16 depicts a shifted threshold voltage distribution of the multi-valued memory. The horizontal axis represents the threshold voltage level, and the vertical axis represents the number of memory cells.

When the plurality of threshold voltage distributions are shifted to the negative side, it is required to apply a negative voltage to the p-type well region 202p of the semiconductor substrate 200 on which the field effect transistor TR_{N} of the sense amplifier 26 is formed. Therefore, a triple well structure is formed by the p-type deep well region 203 and the n-type deep well region 204 to apply the voltage V_{Pwell} which is a negative voltage to the p-type well region 202p. In addition, the voltage V_{DNwell} is applied to the n-type deep well region 204 via the conductor 205. Therefore, for example, when the voltage V_{Pwell} is applied to the p-type well region 202p, the application of the voltage V_{Pwell} to well regions of the other element region other than the triple well structure on the same substrate can be prevented. In addition, the p-type deep well region 203 prevents the voltage V_{DNwell} from causing the influence on the region in the triple well structure.

However, when the triple well structure is formed by the p-type deep well region 203 and the n-type deep well region 204, it is also required to form a contact (electrical connection) to the n-type deep well region 204 on the surface 200a. As the method of forming the contact to the n-type deep well region 204, a method of implanting impurities such as phosphorus or arsenic from the surface 200a is considered. However, in such a case, it is required to form a contact to the n-type deep well region 204 via the p-type deep well region 203, and thus the connection resistance of such a contact is high.

In contrast, by forming the contact to the n-type deep well region 204 by the conductor 205 and the insulator 206, the conductor 205 and the p-type deep well region 203 can be physically separated from each other, and also the conductor 205 can be connected to the n-type deep well region 204. Therefore, the connection resistance of the contact can be reduced. Therefore, the semiconductor device with high reliability can be provided.

When impurities are implanted in order to form the p-type deep well region 203 and the n-type deep well region 204, in a region adjacent to the mask on the surface 200a, impurity ions may be deflected from the side surface of the mask and thus implanted into the corresponding adjacent region. The adjacent region thus has a higher impurity concentration than the other regions of the surface 200a. Therefore, the field effect transistor is preferably formed to avoid the adjacent region. Therefore, for example, when the contact to the n-type deep well region 204 is formed by implanting impurities such as phosphorus or arsenic from the surface 200a, it is required to form a contact avoiding the adjacent region, and thus it is required to increase the size of the region for a peripheral circuit.

In contrast, by forming a contact to the n-type deep well region 204 via the conductor 205 and the insulator 206, the conductor 205 can be connected to the n-type deep well region 204 while still being physically separated from the adjacent region by the insulator 206. Therefore, for example, by forming the conductor 205 in the adjacent region, the peripheral circuit formation region can be designed to be small.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor substrate that includes:
a first surface and a second surface,
a semiconductor region between the first and second surfaces,
a first well region at the first surface and having a donor concentration or an acceptor concentration higher than that of the semiconductor region,
a second well region between the first well region and the second surface and having a higher acceptor concentration than that of the semiconductor region,
a third well region between the second well region and the second surface and having a higher donor concentration than that of the semiconductor region,
a conductor surrounding at least a portion of the first well region along the first surface and extending from the first surface to the third well region in a first direction intersecting the first surface, and
an insulator between the conductor and the first well region and between the conductor and the second well region.

2. The semiconductor device according to claim 1, wherein the conductor comprises polycrystalline semiconductor doped with donor impurities.

3. The semiconductor device according to claim 1, wherein the first well region is electrically connected to a power supply circuit configured to generate a first negative voltage.

4. The semiconductor device according to claim 1, wherein the conductor is electrically connected to a power supply circuit configured to generate a second negative voltage.

5. The semiconductor device according to claim 1, further comprising:
a first field effect transistor having a channel region in the first well region.

6. The semiconductor device according to claim 5, further comprising:
a second field effect transistor, wherein
the semiconductor substrate further includes a fourth well region at the first surface and having a donor concentration or an acceptor concentration higher than that of the semiconductor region,
the second field effect transistor has a channel region in the fourth well region, and
the second well region and the fourth well region are opposite semiconductor type regions.

7. The semiconductor device according to claim 6, wherein the conductor further surrounds at least a portion of the fourth well region along the first surface.

8. The semiconductor device according to claim 7, wherein the semiconductor substrate further includes a shallow trench isolation feature in the first surface between the first and fourth well regions.

9. The semiconductor device according to claim 1, wherein the conductor extends along a second direction parallel to the first surface and a third direction parallel to the first surface and perpendicular to the second direction.

10. The semiconductor device according to claim 1, wherein a dopant concentration of the first well region is higher than the donor concentration of the third well region and the acceptor concentration of the second well region.

11. A semiconductor storage device, comprising:
a memory cell array; and
a peripheral circuit configured to control the memory cell array and including a semiconductor substrate that includes:
a first surface and a second surface,
a semiconductor region between the first and second surfaces,
a first well region at the first surface and having a donor concentration or an acceptor concentration higher than that of the semiconductor region,
a second well region between the first well region and the second surface and having a higher acceptor concentration than that of the semiconductor region,
a third well region between the second well region and the second surface and having a higher donor concentration than that of the semiconductor region,
a conductor surrounding at least a portion of the first well region along the first surface and extending from the first surface to the third well region in a first direction intersecting the first surface, and
an insulator between the conductor and the first well region and between the conductor and the second well region.

12. The semiconductor storage device according to claim 11, wherein the conductor comprises polycrystalline semiconductor doped with donor impurities.

13. The semiconductor storage device according to claim 11, wherein the first well region is electrically connected to a power supply circuit configured to generate a first negative voltage.

14. The semiconductor storage device according to claim 11, wherein the conductor is electrically connected to a power supply circuit configured to generate a second negative voltage.

15. The semiconductor storage device according to claim 11, wherein the peripheral circuit includes a first field effect transistor having a channel region in the first well region.

16. The semiconductor storage device according to claim 15, wherein the peripheral circuit is a sense amplifier that includes the first field effect transistor.

17. The semiconductor storage device according to claim 11, wherein the memory cell array is disposed above the semiconductor substrate of the peripheral circuit in the first direction.

18. The semiconductor storage device according to claim 11, wherein the memory cell array is disposed on a plane including the first surface of the semiconductor substrate.

19. The semiconductor storage device according to claim 11, wherein the memory cell array is disposed on another substrate disposed parallel to the first surface of the semiconductor substrate.

20. A semiconductor storage device, comprising:
a wiring substrate;
a plurality of memory chips stacked on the writing substrate and each including:
a memory cell array, and
a peripheral circuit connected to the memory cell array and including a semiconductor substrate that includes:
a first surface and a second surface,
a semiconductor region between the first and second surfaces,
a first well region in the first surface and having an acceptor concentration greater than that of the semiconductor region,
a second well region between the first well region and the second surface and having a greater acceptor concentration than that of the semiconductor region,
a third well region between the second well region and the second surface and having a greater donor concentration than that of the semiconductor region,
a conductor surrounding at least a portion of the first well region at the first surface and extending from the first surface to the third well region in a first direction intersecting the first surface, and
an insulator between the conductor and the first well region and between the conductor and the second well region; and
a resin layer that covers the wiring substrate and the stacked plurality of memory chips.
